(19) United States
(12) Patent Application Publication
(10) Pub. No.: US 2024/0361590 A1
(43) Pub. Date: Oct. 31, 2024

(54) OPTICAL APPARATUS AND METHOD OF PREVENTING CONTAMINATION OF OPTICAL APPARATUS

(71) Applicant: Lasertec Corporation, Yokohama (JP)

(72) Inventors: Ko GONDAIRA, Yokohama (JP); Masaki INOUE, Yokohama (JP); Haruhiko KUSUNOSE, Yokohama-shi (JP)

(73) Assignee: Lasertec Corporation, Yokohama (JP)

(21) Appl. No.: 18/645,681

(22) Filed: Apr. 25, 2024

(30) Foreign Application Priority Data
Apr. 28, 2023 (JP) 2023-074735

(51) Int. Cl. G02B 27/00; G03F 1/82

(52) U.S. Cl. CPC G02B 27/0006; G03F 1/82

(57) ABSTRACT

To provide an optical apparatus and a method of preventing contamination of the optical apparatus that can more effectively prevent contamination. An optical apparatus according to an embodiment includes a light source configured to generate irradiation light including EUV light, an optical system chamber in which a target object to be irradiated with the irradiation light is disposed, a drop-in mirror provided in the optical system chamber in order to guide the irradiation light, an introducing unit configured to introduce argon into the optical system chamber, a power supply configured to apply a negative voltage to the drop-in mirror in the optical system chamber, an ammeter configured to measure an ion current flowing to the drop-in mirror, and a control unit configured to control an introduction amount of the argon according to a measurement result of the ammeter.

### INCORPORATION BY REFERENCE

This application is based upon and claims the benefit of priority from Japanese patent application No. 2023-074735, filed on Apr. 28, 2023, the disclosure of which is incorporated herein in its entirety by reference.

### BACKGROUND

The present disclosure relates to an optical apparatus and a method of preventing contamination of the optical apparatus.

Published Japanese Translation of PCT International Publication for Patent Application, No. 2013-506308 proposes cleaning a reflection optical element with a cleaning gas in order to reduce contamination in an EUV (Extreme Ultra Violet) lithography apparatus. In Published Japanese Translation of PCT International Publication for Patent Application, No. 2013-506308, a cleaning gas such as atomic hydrogen, hydrogen molecules, or helium is added in the EUV lithography apparatus.

Japanese Unexamined Patent Application Publication No. 2012-256944 discloses a method of removing a contamination layer from an optical surface. In Japanese Unexamined Patent Application Publication No. 2012-256944, a cleaning gas containing atomic hydrogen is brought into contact with the contamination layer. One of cleaning heads uses helium as a sputtering gas. A voltage generator disclosed in Japanese Unexamined Patent Application Publication No. 2012-256944 generates a potential difference between an EUV reflection optical element and the cleaning heads and accelerates helium ions in a cleaning gas jet flow with the generated potential difference.

Japanese Unexamined Patent Application Publication No. 2010-192503 discloses a method of removing an oxide film of a substrate using argon plasma (Ar plasma). In Japanese Unexamined Patent Application Publication No. 2010-192503, the Ar plasma is caused to collide with the substrate, from which a photoresist is removed, in an oxygen-free atmosphere to remove a natural oxide film.

Japanese Patent No. 6844798 discloses that an optical element is cleaned by hydrogen plasma or helium plasma (He plasma). In Japanese Patent No. 6844798, the hydrogen plasma or the He plasma is generated by a remote plasma generation apparatus and introduced into a chamber.

### SUMMARY

EUV light is absorbed by air and nitrogen. Therefore, an optical system of the EUV light is operated in a vacuum chamber. At that time, lubricant used for mechanical components and an organic residual gas generated from an electric wiring material and the like are absorbed on optical component surfaces. When the absorbed organic residual gas is irradiated with the EUV light, organic molecules are decomposed and carbon adheres to the component surfaces. Consequently, there is a problem in that the reflectance of a mirror is deteriorated.

There is a technique of cleaning optical elements such as a mirror by removing contaminants such as carbon adhering to the optical elements with hydrogen plasma or He plasma. However, a method of further increasing an etching rate to clean contaminants has been desired.

The present disclosure has been made in view of the problems described above and provides an optical apparatus and a method of preventing contamination of the optical apparatus that can more effectively prevent contamination of an optical element.

An optical apparatus according to an aspect of an embodiment includes: a light source configured to generate light including EUV light; a chamber in which a target object to be irradiated with the light is disposed; an optical element provided in the chamber in order to guide the light; an introducing unit configured to introduce argon into the chamber; a power supply configured to apply a negative voltage to the optical element in the chamber; an ammeter configured to measure an ion current flowing to the optical element; and a control unit configured to control an introduction amount of the argon according to a measurement result of the ammeter.

In the optical apparatus explained above, the argon introduced into the chamber may contain an argon gas, the introducing unit may include an introducing pipe connected to the chamber, the control unit may control a flow rate of the argon gas supplied into the chamber via the introducing pipe, and the EUV light guided in the chamber may convert the argon gas into argon plasma.

In the optical apparatus explained above, the introducing unit may include: a remote plasma generation apparatus configured to generate argon plasma; an introducing pipe provided between the remote plasma generation apparatus and the chamber; and a variable conductance valve provided in the introducing pipe, and the control unit may control conductance of the variable conductance valve to thereby control a flow rate of the argon plasma supplied into the chamber via the introducing pipe.

In the optical apparatus explained above, a cooling mechanism that cools the introducing pipe may be provided.

In the optical apparatus explained above, the target object may be an EUV mask including a pellicle.

In the optical apparatus explained above, the argon introduced into the chamber may contain an argon gas, the light source may further generate the light including VUV light, an oblique incidence mirror that reflects the VUV light may be provided in the chamber, the VUV light reflected by the oblique incidence mirror may be made incident on the optical element, and the VUV light guided into the chamber may convert the argon gas into argon plasma.

A method of preventing contamination of an optical apparatus according to an aspect of an embodiment is a method of preventing contamination of an optical apparatus including: a light source configured to generate light including EUV light; a chamber in which a target object to be irradiated with the light is disposed; and an optical element provided in the chamber in order to guide the light, the method including: a step of introducing argon into the chamber; a step of applying a negative voltage to the optical element in the chamber; a step of measuring an ion current flowing to the optical element; and a step of controlling an introduction amount of the argon according to a measurement result of the ion current.

In the method of preventing contamination explained above, an introducing pipe may be connected to the chamber, in the step of introducing argon into the chamber, the argon introduced into the chamber may contain an argon gas, in the step of controlling an introduction amount of the argon according to a measurement result of the ion current, a flow rate of the argon gas supplied into the chamber via the introducing pipe may be controlled according to the measurement result, and the EUV light guided into the chamber may convert the argon gas into argon plasma.

In the method of preventing contamination explained above, the optical apparatus may include: a remote plasma generation apparatus configured to generate argon plasma; an introducing pipe provided between the remote plasma generation apparatus and the chamber; and a variable conductance valve provided in the introducing pipe, in the step of introducing argon into the chamber, the argon introduced into the chamber may contain the argon plasma, and, in the step of controlling an introduction amount of the argon according to a measurement result of the ion current, conductance of the variable conductance valve may be controlled according to the measurement result to control a flow rate of the argon plasma supplied into the chamber via the introducing pipe.

In the method of preventing contamination explained above, a cooling mechanism that cools the introducing pipe may be provided.

In the method of preventing contamination explained above, the target object may be an EUV mask including a pellicle.

In the method of preventing contamination explained above, the light source may further generate the light including VUV light, an oblique incidence mirror that reflects the VUV light may be provided in the chamber, the VUV light reflected by the oblique incidence mirror may be made incident on the optical element, and the VUV light guided into the chamber may convert the argon gas into argon plasma.

According to the present disclosure, it is possible to provide an optical apparatus and a method of preventing contamination of the optical apparatus that can more effectively prevent contamination of an optical element.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a schematic diagram illustrating an optical apparatus according to a first embodiment;

FIG. 2 is a flowchart illustrating a method of preventing contamination of the optical apparatus according to the first embodiment;

FIG. 3 is a schematic diagram illustrating an optical apparatus according to a second embodiment;

FIG. 4 is a schematic diagram illustrating an optical apparatus according to a third embodiment; and

FIG. 5 is a schematic diagram illustrating an optical apparatus according to a fourth embodiment.

### DESCRIPTION OF EMBODIMENTS

Embodiments of the present disclosure are explained below with reference to the drawings. The following explanation indicates preferred embodiments of the present disclosure. The scope of the present disclosure is not limited to the embodiments explained below. In the following explanation, components denoted by the same reference numerals and signs indicate substantially the same contents.

### Overview of an Embodiment

An optical apparatus according to an embodiment includes a function of preventing contamination of an optical element disposed in the apparatus. Specifically, the optical apparatus prevents contamination of the optical element using Ar plasma. Examples of a method of generating Ar plasma include the following two methods.
1. Introducing an argon gas (Ar gas) into an EUV optical path.
2. Using a remote plasma generation apparatus.

First, in a first embodiment explained below, an optical apparatus and a method of preventing contamination that introduce an Ar gas into an EUV optical path are explained. In a second embodiment, an optical apparatus and a method of preventing contamination that use a remote plasma generation apparatus are explained. In a third embodiment, an optical apparatus and a method of preventing contamination that introduce an Ar gas into a VUV optical path are explained. In a fourth embodiment, a mechanism of cooling an introducing pipe for Ar plasma is explained.

### First Embodiment

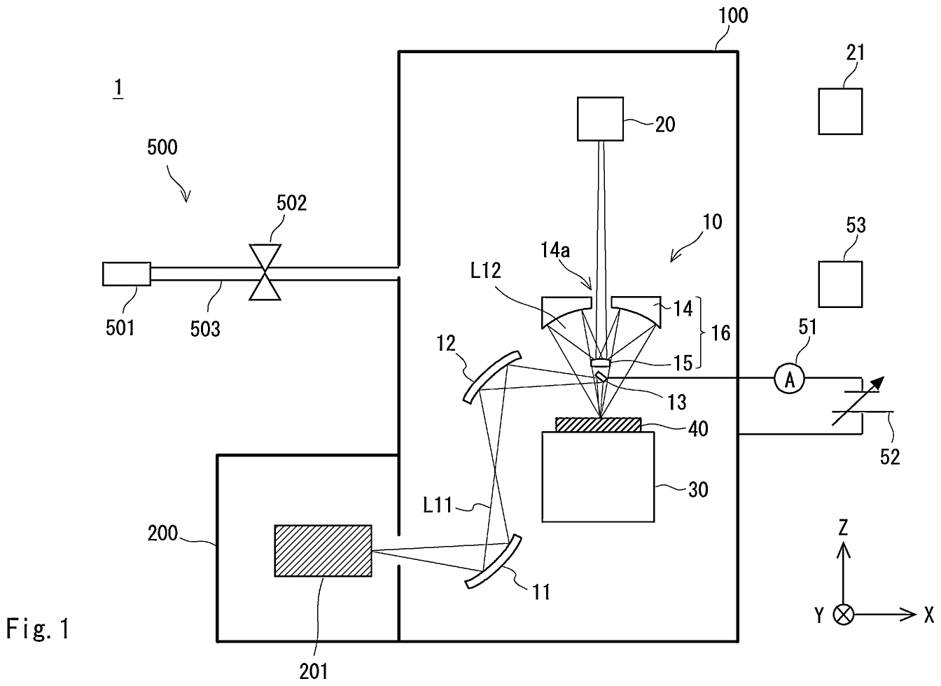

An optical apparatus according to a first embodiment is explained. FIG. 1 is a schematic diagram illustrating the optical apparatus according to the first embodiment. As illustrated in FIG. 1, in this embodiment, the optical apparatus is, for example, an inspection apparatus 1 that inspects an EUV mask using EUV light. In that case, a sample 40 is an EUV mask. The EUV mask serving as the sample 40 may be a patterned mask or may be a pattern-less mask blank. Note that the optical apparatus is not limited to the inspection apparatus 1 and may be another optical apparatus such as an exposure apparatus if the optical apparatus can control atmosphere in the apparatus. The sample 40 is not limited to the EUV mask if the sample 40 is a light irradiation target object.

### Apparatus Configuration

The inspection apparatus 1 according to this embodiment includes an optical system chamber 100, a light source chamber 200, an introducing unit 500, an ammeter 51, a power supply 52, and a control unit 53.

The light source chamber 200 is a vacuum chamber and is connected to a not-illustrated vacuum pump. A light source 201 is disposed in the light source chamber 200.

The light source 201 generates light including EUV light. Here, the light source 201 generates EUV light having a wavelength of 13.5 nm that is the same as an exposure wavelength of the sample 40, which is an irradiation target. Light generated by the light source 201 is represented as irradiation light L11. The light source 201 is, for example, a DPP (Discharge Produced Plasma) light source that uses electric discharge. The light source 201 may further generate, in addition to the EUV light, VUV (Vacuum Ultra Violet) light, which is out-of-band light. The light source 201 may generate light including at least one of the VUV light and the EUV light. Note that the VUV light may be light having a wavelength of 100 nm or more and 200 nm or less.

The optical system chamber 100 is a vacuum chamber and is connected to a not-illustrated vacuum pump. The optical system chamber 100 is connected to the light source chamber 200. Since internal spaces of the light source chamber 200 and the optical system chamber 100 are in a vacuum state, the EUV light is propagated in vacuum. Note that exhaust of the light source chamber 200 and the optical system chamber 100 may be performed by a common vacuum pump or may be performed by separate vacuum pumps.

An optical system 10, a photodetector 20, a stage 30, and the sample 40 are disposed in the optical system chamber 100. The optical system 10 includes an optical element and propagates the irradiation light L11, which is the EUV light. The optical system 10 includes, as optical elements, a concave mirror 11, a concave mirror 12, a drop-in mirror 13, and a Schwarzschild optical system 16. The optical elements may be provided in the optical system chamber 100 in order to guide the irradiation light L11. The optical system 10 is a dark field optical system for imaging the sample 40. Note that the optical system 10 may be a bright field optical system for imaging the sample 40. The sample 40 is disposed in the optical system chamber 100. The sample 40 is a target object irradiated with the irradiation light L11.

The optical system 10 for guiding the EUV light is explained below. The irradiation light L11 generated by the light source 201 travels while spreading. The irradiation light L11 generated from the light source 201 is reflected on the concave mirror 11. The concave mirror 11 is, for example, an ellipsoidal mirror. The concave mirror 11 is a multilayer film mirror in which Mo films and Si films are alternately stacked. The concave mirror 11 reflects the EUV light. The irradiation light L11 reflected on the concave mirror 11 travels while being narrowed. After being focused, the irradiation light L11 travels while spreading. Then, the irradiation light L11 is reflected on the concave mirror 12.

The concave mirror 12 is, for example, an ellipsoidal mirror. The concave mirror 12 is a multilayer film mirror in which Mo films and Si films are alternately stacked. The concave mirror 12 reflects the EUV light. The irradiation light L11 reflected on the concave mirror 12 travels while being narrowed and is made incident on the drop-in mirror 13. The drop-in mirror 13 is a plane mirror and is disposed straightly above the sample 40. The irradiation light L11 reflected on the drop-in mirror 13 is made incident on the sample 40. The drop-in mirror 13 condenses the irradiation light L11 on the sample 40. In this way, an inspect region of the sample 40 is illuminated by the irradiation light L11, which is the EUV light. Therefore, the irradiation light L11 serves as illumination light that illuminates the sample 40.

The stage 30 is provided in the optical system chamber 100. The sample 40 is placed on the stage 30. The stage 30 is a drive stage such as an XYZ stage. The stage 30 moves in an XY plane perpendicular to an optical axis and in a Z-axis direction parallel to the optical axis, whereby the sample 40 moves. Consequently, since an illumination position of the sample 40 changes, it is possible to observe any position of the sample 40. It is possible to change an inspect region where the sample 40 is illuminated.

Next, a detection optical system that detects light reflected from the sample 40 is explained. As explained above, the irradiation light L11 illuminates the inspect region of the sample 40. The EUV light reflected on the sample 40 is represented as detection light L12. The detection light L12 reflected on the sample 40 is made incident on the Schwarzschild optical system 16. The Schwarzschild optical system 16 includes a concave mirror with hole 14 and a convex mirror 15 disposed on the sample 40.

The detection light L12 reflected on the sample 40 is made incident on the concave mirror with hole 14. A hole 14a is provided in the center of the concave mirror with hole 14. The detection light L12 reflected on the concave mirror with hole 14 is made incident on the convex mirror 15. The convex mirror 15 reflects, toward the hole 14a of the concave mirror with hole 14, the detection light L12 reflected from the concave mirror with hole 14. The detection light L12 passed through the hole 14a of the concave mirror with hole 14 is made incident on the photodetector 20. The inspect region of the sample 40 is enlarged and projected on the photodetector 20 by the Schwarzschild optical system 16.

The detection light L12 reflected on the convex mirror 15 is detected by the photodetector 20. The photodetector 20 is an imaging apparatus such as a CCD (Charge Coupled Device) sensor, a CMOS (Complementary Metal Oxide Semiconductor) sensor, or a TDI (Time Delay Integration) sensor and images the sample 40. That is, the photodetector 20 captures an enlarged image of the inspect region of the sample 40.

The image of the sample 40 captured by the photodetector 20 is output to a processing apparatus 21. The processing apparatus 21 is an arithmetic processing apparatus including a processor and a memory and performs an inspection based on the image of the sample 40. For example, the processing apparatus 21 performs a defect inspection by comparing the luminance of the image of the sample 40 with a threshold. The processing apparatus 21 controls a coordinate of the stage 30. This makes it possible to specify a defect coordinate of the sample 40. The processing apparatus 21 stores the defect coordinate and an image of a defect in the memory or the like. The processing apparatus 21 displays the image of the defect or the like on a monitor. Consequently, a user can check the defect.

The ammeter 51, the power supply 52, and the control unit 53 are disposed on the outer side of the optical system chamber 100. The power supply 52 is connected to an optical element. When the optical element is the drop-in mirror 13, the power supply 52 is connected to the drop-in mirror 13. The power supply 52 is a DC (Direct Current) power supply and generates a DC voltage. The power supply 52 supplies a negative DC voltage to the drop-in mirror 13. For example, the optical system chamber 100 has ground potential and the drop-in mirror 13 has negative potential. The ammeter 51 is connected between the power supply 52 and the drop-in mirror 13. The ammeter 51 measures an ion current flowing to the optical element. When the optical element is the drop-in mirror 13, the ammeter 51 measures an electric current flowing from the power supply 52 to the drop-in mirror 13. The control unit 53 controls, according to a measurement result of the ammeter 51, an introduction amount of argon introduced into the optical system chamber 100.

### Contamination Prevention

Next, a method of preventing contamination of an optical apparatus is explained. Mechanical components and electric wiring materials are provided in the optical system chamber 100 and the light source chamber 200. An organic residual gas is generated from lubricant used in the mechanical components, the electric wiring materials, and the like and is absorbed on an optical element surface. When the optical element is irradiated with EUV light, a contaminant such as carbon is deposited on the optical element surface.

The method of preventing contamination in this embodiment generates Ar plasma and etches, with the generated Ar plasma, the contaminant deposited on the optical element. Consequently, the contaminant of the optical element is removed.

An etching rate of the optical element can be controlled mainly by the following two parameters.
A. Density of the Ar plasma
B. Bias voltage applied to the optical element

First, a method of controlling the density of the Ar plasma is explained. Thereafter, a method of controlling a bias voltage applied to the optical element is explained.

### Density of the Ar Plasma

The density of the Ar plasma in this embodiment is controlled according to a flow rate of argon introduced into the optical system chamber 100. In this embodiment, the argon introduced into the optical system chamber 100 contains an Ar gas. In the following explanation, an example is explained in which contamination of the drop-in mirror 13 is prevented as removal of contamination of the optical element.

As illustrated in FIG. 1, the irradiation light L11 reflected on the concave mirror 12 travels while being narrowed. For this reason, in the drop-in mirror 13, a spot of the irradiation light L11 decreases in size. The light density of the irradiation light L11 increases in the drop-in mirror 13 and contamination of the drop-in mirror 13 is accelerated. Therefore, in this embodiment, the drop-in mirror 13 is an optical element that is a target of contamination prevention.

In this embodiment, the introducing unit 500 is provided in order to remove contamination of the optical element. The introducing unit 500 introduces an Ar gas into the optical system chamber 100. The introducing unit 500 includes a gas supply unit 501, an MFC (Mass Flow Controller) 502, and an introducing pipe 503.

The gas supply unit 501 includes a gas cylinder and supplies the Ar gas. The gas supply unit 501 is connected to the introducing pipe 503. The gas supply unit 501 supplies the Ar gas to the introducing pipe 503.

The introducing pipe 503 is connected to the optical system chamber 100. Accordingly, the Ar gas from the gas supply unit 501 is supplied to the optical system chamber 100 through the introducing pipe 503. The MFC 502 is provided in the introducing pipe 503. The MFC 502 controls a flow rate of gas. The control unit 53 outputs a control signal to the MFC 502 according to a measurement result of the ammeter 51. The MFC 502 controls the gas flow rate based on the control signal.

As explained above, the control unit 53 controls the flow rate of the Ar gas supplied into the optical system chamber 100 via the introducing pipe 503. EUV light guided into the optical system chamber 100 converts the Ar gas into Ar plasma. For example, the Ar gas introduced onto an optical path is irradiated with the irradiation light L11 made incident on the drop-in mirror 13 to be converted into Ar plasma. Note that the Ar gas absorbs the EUV light. Accordingly, a flow rate of the Ar gas may be determined considering the absorption by the EUV light.

### Bias Voltage Applied to the Optical Element

Next, a bias voltage applied to the optical element is explained. As explained above, the EUV light converts the Ar gas into the Ar plasma. The generated Ar plasma includes Ar ions (Ar₊) and travels to the optical element to which a negative voltage is applied. Therefore, by changing the bias voltage applied to the optical element, energy for causing the Ar plasma to collide with the optical element can be changed. This makes it possible to change an etching rate by the Ar plasma. Accordingly, by changing the bias voltage according to a contamination state of the optical element, it is possible to exert an appropriate cleaning effect. Details are explained below.

The drop-in mirror 13 is disposed on the inside of the optical system chamber 100. A DC voltage is applied between the optical system chamber 100 and the drop-in mirror 13. For this reason, an electric field is generated around the drop-in mirror 13 and the generated Ar plasma is accelerated. The Ar plasma collides with the drop-in mirror 13. Consequently, the Ar plasma can etch contamination of the drop-in mirror 13. That is, the Ar ions are accelerated by the electric field and collide with the surface of the optical element, whereby carbon can be removed. Accordingly, it is possible to suppress deterioration in the reflectance of the drop-in mirror 13.

A negative DC voltage applied to the drop-in mirror 13 is preferably set to a level for preventing the drop-in mirror 13 from being damaged by collision of ions. For example, a voltage of −50 V to −100 V is applied to the drop-in mirror 13. This makes it possible to effectively remove carbon adhering to the surface of the drop-in mirror 13.

The ammeter 51 monitors an electric current flowing from the power supply 52 to the drop-in mirror 13. Specifically, since the Ar ions collide with the drop-in mirror 13, an electric current flows from the drop-in mirror 13 to the power supply 52. That is, the ammeter 51 measures an ion current that has collided with the drop-in mirror 13.

The control unit 53 controls an introduction amount of the Ar gas according to a measurement result of the ammeter 51. For example, the control unit 53 controls an opening degree of the MFC 502 according to the measurement result of the ammeter 51. A target value may be set in the control unit 53 such that the measured ion current becomes an ion current corresponding to the surface area of the optical element. The control unit 53 feedback-controls the MFC 502 such that the ion current measured by the ammeter 51 reaches the target value. Note that, when the drop-in mirror 13 is irradiated with the EUV light, a photoemission current is superimposed on a measurement current. Therefore, it is preferable to set the target value in a state in which the drop-in mirror 13 is not irradiated with the EUV light.

The introducing unit 500 can introduce the Ar gas during the inspection of the sample 40. That is, it is possible to implement the method of preventing contamination in parallel to the inspection of the sample 40. This makes it possible to improve productivity.

Argon has high mass compared with helium and hydrogen. Accordingly, energy at the time when the Ar plasma collides with the optical element is large. Therefore, the etching rate by the Ar plasma is higher than etching rates by He plasma and hydrogen plasma. This makes it possible to further improve a contamination prevention effect than methods of using the He plasma and the hydrogen plasma.

Since the argon has a high EUV light absorption coefficient, it is likely that the argon reduces the EUV light that illuminates the sample 40. However, since the etching rate of the Ar plasma is high as explained above, it is possible to reduce the pressure of the Ar gas. In addition, if the bias voltage is increased, it is possible to further reduce the pressure of the Ar gas. This makes it possible to improve the contamination prevention effect while suppressing the decrease in the EUV light that illuminates the sample 40.

Since the Ar gas has large mass compared with hydrogen and helium, it is possible to suppress debris scattering that occurs from the light source 201.

Further, when the sample 40 is an EUV mask attached with a pellicle, it is possible to prevent damage to the pellicle. A reason for this is explained below.

The pellicle attached to the EUV mask is extremely thin and is easy to be torn. One of causes of this is charging of the pellicle. Since the pellicle is insulated, photoelectrons are emitted by irradiation of the EUV light. When the photoelectrons are emitted from the pellicle, the pellicle is charged at plus potential. When the pellicle is charged at high potential and electrostatically broken to discharge electricity, the pellicle is sometimes damaged in a part where the electric discharge has occurred. Since tensile stress is applied to the pellicle, the damage sometimes spreads starting from the electric discharge part. The pellicle is sometimes torn when excessively large force is applied to the pellicle by the Coulomb force.

In this embodiment, the Ar plasma is generated in the optical system chamber 100 by the EUV light. When the pellicle emits the photoelectrons and is charged at the plus potential, electrons in plasma are absorbed by the pellicle and can be neutralized. In this case, since the potential of the pellicle is suppressed to floating potential in the plasma, the electric discharge can be prevented.

The Ar gas introduced by the introducing unit 500 has an effect of driving out a residual gas from the optical system chamber 100.

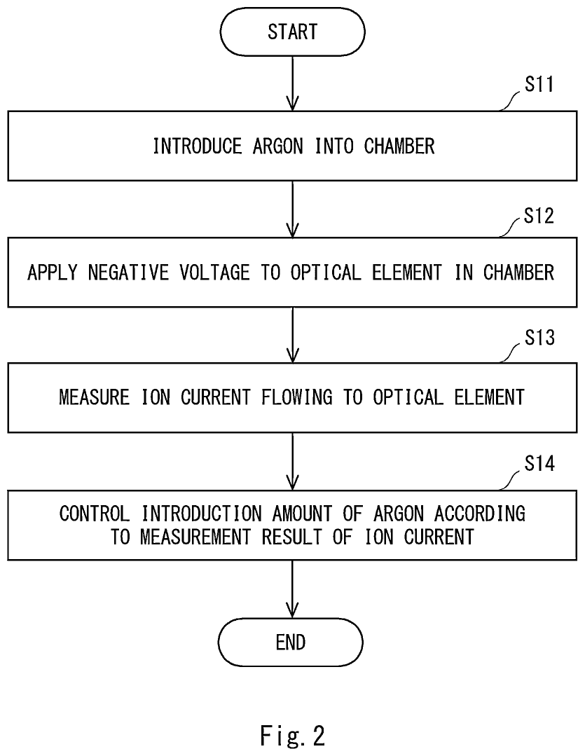

Next, a method of preventing contamination of an optical apparatus according to this embodiment is explained. FIG. 2 is a flowchart illustrating a method of preventing contamination of an optical apparatus according to the first embodiment. As illustrated in FIG. 2, the method of preventing contamination of the optical apparatus includes step S11 of introducing argon into the optical system chamber 100, step S12 of applying a negative voltage to an optical element such as the drop-in mirror 13 in the optical system chamber 100, step S13 of measuring an ion current flowing to the optical element, and step S14 of adjusting an introduction amount of argon according to a measurement result of the ion current.

In this embodiment, in a step of introducing argon into the chamber in step S11, the argon introduced into the optical system chamber 100 contains an Ar gas. In a step of controlling an introduction amount of the argon according to a measurement result of an ion current in step S14, a flow rate of the Ar gas supplied into the optical system chamber 100 via the introducing pipe 503 is controlled according to the measurement result. The EUV light guided into the optical system chamber 100 converts the Ar gas into Ar plasma.

In this embodiment, the optical element prevented from being contaminated is the drop-in mirror 13. However, other optical elements and optical components may be prevented from being contaminated. For example, the concave mirror 11, the concave mirror 12, the concave mirror with hole 14, and the convex mirror 15 may be prevented from being contaminated. In this case, a negative DC voltage only has to be applied to an optical element desired to be prevented from being contaminated. Note that a negative voltage may be simultaneously applied to two or more optical elements. This makes it possible to prevent the two or more optical elements from being contaminated.

As explained above, in this embodiment, the introducing unit 500 introduces argon into the optical system chamber 100. This makes it possible to more effectively prevent contamination of the optical element. In contrast, when carbon is oxidized and removed by an oxygen radical, it is necessary to irradiate high-energy EUV light. That is, it has been necessary to activate an optical element surface or oxygen and dissociate oxygen molecules into radicals. However, it has been difficult to irradiate an amount of light corresponding to the film thickness of carbon on the optical element surface. Removal results have been prone to nonuniformity. Since the surface of silicon or the like is easily oxidized by the oxygen radical, it is likely that, after deposited carbon is removed, the silicon is exposed and oxidized, resulting in deterioration in reflectance. In contrast, in this embodiment, since argon is used, it is possible to easily prevent contamination.

### Second Embodiment

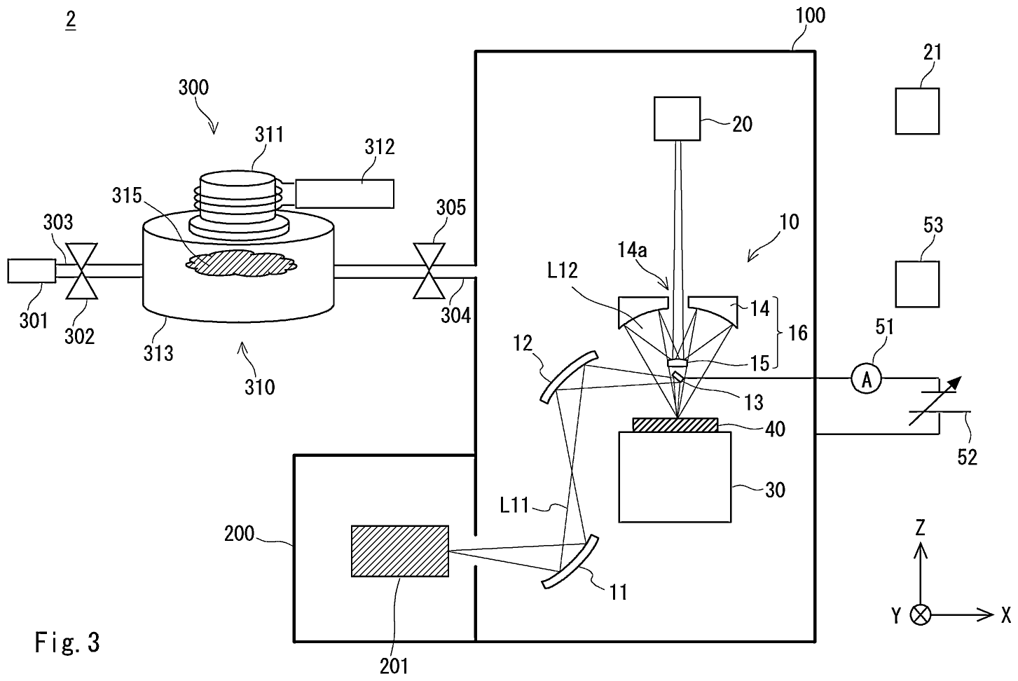

Next, an optical apparatus according to a second embodiment is explained. FIG. 3 is a schematic diagram illustrating an inspection apparatus according to the second embodiment. As illustrated in FIG. 3, in an inspection apparatus 2 in this embodiment, an introducing unit 300 is provided instead of the introducing unit 500. In this embodiment, argon introduced into the optical system chamber 100 contains Ar plasma. The introducing unit 300 includes a gas supply source 301, an MFC 302, a gas pipe 303, an introducing pipe 304, a variable conductance valve 305, and a remote plasma generation apparatus 310. The remote plasma generation apparatus 310 generates remote plasma of argon.

The gas supply source 301 includes a gas cylinder or the like that stores an Ar gas. The gas supply source 301 is connected to the remote plasma generation apparatus 310 via the gas pipe 303. The gas supply source 301 supplies the Ar gas to the remote plasma generation apparatus 310. The Ar gas from the gas supply source 301 is introduced into the remote plasma generation apparatus 310 via a gas pipe 303. The introduced Ar gas is filled into a plasma chamber 313 of the remote plasma generation apparatus 310. The MFC 302 is provided in the gas pipe 303. The MFC 302 controls a flow rate of the Ar gas.

The remote plasma generation apparatus 310 includes a coil 311, an RF (Radio Frequency) power supply 312, and the plasma chamber 313. The plasma chamber 313 is a vacuum chamber and is connected to a not-illustrated vacuum pump. The Ar gas from the gas supply source 301 is filled into the plasma chamber 313. The RF power supply 312 supplies an RF voltage to the coil 311. Consequently, since an electric current flows to the coil 311, a magnetic field is generated in the plasma chamber 313. Ar molecules are ionized into Ar ions (Ar₊) and electrons and plasma 315 is generated. The plasma 315 may be generated not only by inductive coupling but also by capacitive coupling. The plasma 315 may be generated using RF glow discharge. Alternatively, ECR (Electron Cyclotron Resonance) plasma may be used as the plasma 315.

The introducing pipe 304 is connected to the plasma chamber 313. Further, the introducing pipe 304 is connected to the optical system chamber 100. That is, the introducing pipe 304 is provided between the remote plasma generation apparatus 310 and the optical system chamber 100. The plasma chamber 313 is connected to the optical system chamber 100 via the introducing pipe 304. The plasma 315 generated in the plasma chamber 313 is introduced into the optical system chamber 100 through the introducing pipe 304. The variable conductance valve 305 is provided in the introducing pipe 304. The conductance (an opening degree) of the variable conductance valve 305 is variable.

The control unit 53 changes the opening degree of the variable conductance valve 305. The control unit 53 controls the conductance of the variable conductance valve 305 to thereby control a flow rate of the Ar plasma supplied into the optical system chamber 100 via the introducing pipe 304. For example, when the conductance of the variable conductance valve 305 is increased, an introduction amount of the plasma 315 increases. Conversely, when the conductance of the variable conductance valve 305 is reduced, the introduction amount of the plasma 315 decreases. The control unit 53 may control the RF power supply 312. Consequently, since the density of the plasma 315 can be controlled, it is possible to adjust the introduction amount of the plasma 315.

As explained above, the introducing unit 300 introduces the plasma 315 into the optical system chamber 100. That is, the remote plasma generation apparatus 310 generates the plasma 315. The plasma 315 containing the electrons, the Ar ions, the Ar gas, and the radical is introduced into the optical system chamber 100.

In this embodiment, the introducing unit 300 includes the remote plasma generation apparatus 310. Ar plasma can be generated in another plasma chamber 313 separated from the optical system chamber 100. Since the plasma chamber 313 and the optical system chamber 100 are connected by the introducing pipe 304, the plasma chamber 313 and the optical system chamber 100 can be thermally sparsely coupled. The heat of the remote plasma generation apparatus 310 is less easily transmitted to the optical system chamber 100. The accuracy of the optical system 10 can be kept high.

In this embodiment, the plasma 315 is introduced into the optical system chamber 100. When photoelectrons are emitted and a pellicle is charged at plus potential, electrons in the plasma 315 are absorbed by the pellicle and can be neutralized. In this case, since the potential of the pellicle is suppressed to floating potential in the plasma 315, electric discharge can be prevented.

Ar introduced by the introducing unit 300 is not limited to the Ar plasma and may be neutral Ar molecules (Ar gas). In this case as well, there is an effect of driving out a residual gas from the chamber.

Note that, in the above explanation, the Ar plasma generated by the remote plasma generation apparatus 310 is used. However, He plasma and hydrogen plasma generated by the remote plasma generation apparatus 310 may be used. For example, when an optical element surface is coated with a substance having high hydrogen radical resistance such as ruthenium, the hydrogen plasma can be used. When the hydrogen plasma is used, since hydrogen has smaller mass than He and Ar, an ion impact effect is small. Therefore, the voltage of the power supply 52 is increased. Consequently, since speed energy of ions increases, it is possible to effectively prevent contamination.

Further, the hydrogen introduced into the optical system chamber 100 is not limited to the hydrogen plasma and may be a hydrogen gas, a hydrogen radical, or the like. Naturally, the introducing unit 300 may mix and introduce gas, plasma, a radical, and the like. That is, the introducing unit 300 only has to introduce argon, hydrogen, or helium into the chamber.

In the method of preventing contamination of the optical apparatus according to this embodiment, in the step of introducing argon into the optical system chamber 100 in step S11 explained above, the argon introduced into the optical system chamber 100 contains Ar plasma. In the step of controlling an introduction amount of the argon according to a measurement result of the ion current in step S14, the control unit 53 controls the conductance of the variable conductance valve 305 according to the measurement result to thereby control a flow rate of the Ar plasma supplied into the optical system chamber 100 via the introducing pipe 304. This makes it possible to effectively prevent contamination of the optical element. Components and effects other than the above are included in the description of the first embodiment.

### Third Embodiment

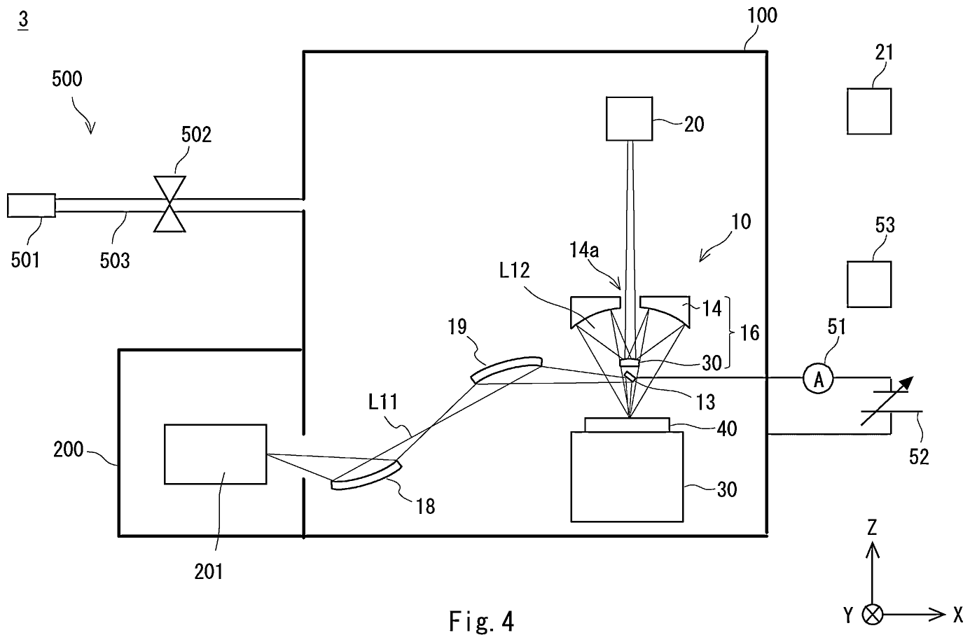

Next, an optical apparatus according to a third embodiment is explained. FIG. 4 is a schematic diagram illustrating the optical apparatus according to the third embodiment. As illustrated in FIG. 4, in an inspection apparatus 3 in this embodiment, a concave mirror 18 and a concave mirror 19 are provided instead of the concave mirror 11 and the concave mirror 12 illustrated in FIG. 1. The concave mirror 18 and the concave mirror 19 are oblique incidence mirrors. The light source 201 generates light including VUV light in addition to EUV light. Components other than the concave mirror 18 and the concave mirror 19 are the same as the components illustrated in FIG. 1. Therefore, explanation of the components is omitted as appropriate. For example, the Schwarzschild optical system 16 has the same configuration as the configuration in the first embodiment.

Since the concave mirror 18 and the concave mirror 19 are the oblique incidence mirrors, the optical axes of the irradiation light L11 before and after reflection of the concave mirror 18 are not orthogonal. On the other hand, in the concave mirror 11 in the first embodiment, since the concave mirror 11 is tilted 45 degrees with respect to the optical axis of the irradiation light L11, the optical axes of the irradiation light L11 before and after reflection of the concave mirror 11 are orthogonal.

Similarly, the optical axes of the irradiation light L11 before and after reflection of the concave mirror 19 are not orthogonal. On the other hand, in the concave mirror 12 in the first embodiment, since the concave mirror 12 is tilted 45 degrees with respect to the optical axis of the irradiation light L11, the optical axes of the irradiation light L11 before and after reflection of the concave mirror 12 are orthogonal.

As with the first embodiment, the irradiation light L11 reflected on the concave mirror 18 and the concave mirror 19 is made incident on the drop-in mirror 13. The drop-in mirror 13 reflects the irradiation light L11, whereby the sample 40 is illuminated. Accordingly, as with the first embodiment, the photodetector 20 can image the sample 40.

The concave mirrors 18 and 19, which are the oblique incidence mirrors, are metal mirrors. For example, the concave mirrors 18 and 19 are metal mirrors on which Ru (ruthenium) films are formed. Since the concave mirrors 18 and 19 are metal mirrors, the concave mirrors 18 and 19 reflect VUV light and EUV light emitted from the light source 201. That is, not only the EUV light but also the VUV light is guided to the drop-in mirror 13. In contrast, in the first embodiment, since the concave mirror 11 and the concave mirror 12 are the multilayer film mirrors, most of the VUV light is not guided to the drop-in mirror 13.

By using the oblique incidence mirrors as the concave mirrors 18 and 19, the VUV light can be guided to the drop-in mirror 13. The irradiation light L11 reflected on the concave mirror 19 includes the EUV light and the VUV light. The concave mirror 19 condenses the irradiation light L11 on the sample 40. Since the irradiation light L11 reflected on the concave mirror 19 travels while being narrowed, the light density of the irradiation light L11 increases in the vicinity of the drop-in mirror 13. Further, an Ar gas is supplied to the optical system chamber 100.

The EUV light and the VUV light included in the irradiation light L11 are absorbed by the Ar gas. The Ar gas is ionized in the vicinity of the drop-in mirror 13 having high light density and Ar plasma is generated. A negative DC voltage is applied to the drop-in mirror 13 as with the first embodiment. Accordingly, the Ar plasma collides with the drop-in mirror 13. That is, the VUV light guided into the optical system chamber 100 converts the Ar gas into the Ar plasma. This makes it possible to prevent contamination as with the first embodiment.

Note that, in this embodiment, the control unit 53 controls the MFC 502 according to the measurement result of the ammeter 51. That is, the MFC 502 controls a gas flow rate such that a measurement value of the ammeter 51 reaches a target value. This makes it possible to appropriately adjust an introduction amount of argon into the optical system chamber 100. Accordingly, it is possible to effectively prevent contamination.

In this embodiment, plasma is generated using the VUV light, which is out-of-band light, generated by the light source 201. That is, the Ar plasma can be generated by the light source 201 for an inspection. Accordingly, since the remote plasma generation apparatus 310 is unnecessary, it is possible to simplify an apparatus configuration. Since the introducing unit 500 that introduces the Ar gas only has to be added, it is possible to suppress an increase in apparatus costs.

In the method of preventing contamination of the optical apparatus according to this embodiment, in the step of introducing argon into the optical system chamber 100 in step S11 explained above, the argon introduced into the optical system chamber 100 contains Ar plasma. In the step of controlling an introduction amount of argon according to a measurement result of the ion current in step S14, the control unit 53 controls, according to the measurement result, a flow rate of an Ar gas supplied into the optical system chamber 100 via the introducing pipe 503. The VUV light guided into the optical system chamber 100 converts the Ar gas into Ar plasma. This makes it possible to effectively prevent contamination of the optical element.

### Fourth Embodiment

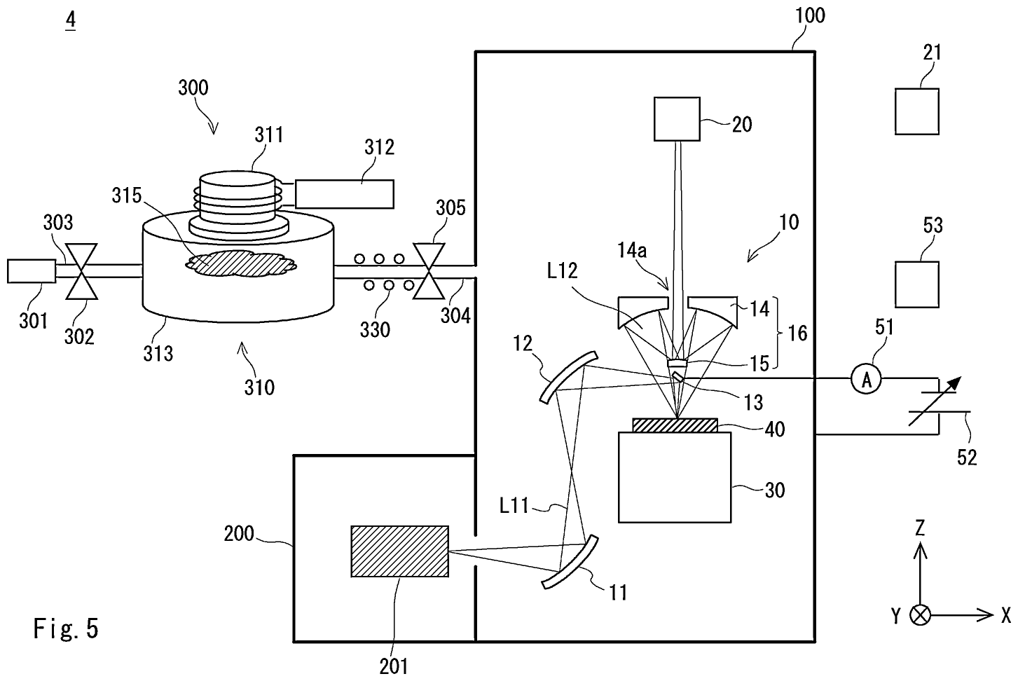

Next, an optical apparatus according to a fourth embodiment is explained. FIG. 5 is a schematic diagram illustrating the optical apparatus according to the fourth embodiment. As illustrated in FIG. 5, in an inspection apparatus 4 in this embodiment, a cooling mechanism 330 is added to the introducing unit 300 in addition to the components illustrated in FIG. 3. Components other than the cooling mechanism 330 are the same as the components in the second embodiment. Therefore, explanation of the components is omitted.

The cooling mechanism 330 includes, for example, a water cooling jacket in which cooling water flows. The cooling mechanism 330 is attached to the introducing pipe 304. Note that an attachment position of the cooling mechanism 330 is not limited to the introducing pipe 304 and may be the plasma chamber 313 or the like.

The cooling mechanism 330 cools the introducing pipe 304. Accordingly, it is possible to prevent heat generated in the remote plasma generation apparatus 310 from being conducted to the optical system chamber 100. This makes it possible to stabilize the temperature of the optical system chamber 100. It is possible to suppress deviation of the optical system 10 due to thermal expansion or the like. It is possible to perform a highly accurate inspection.

The configurations of the first to fourth embodiments may be combined as appropriate. For example, the concave mirrors 18 and 19, which are the oblique incidence mirrors, may be used in the first, second, and fourth embodiments. Further, both of gas and plasma may be introduced. That is, the introducing unit 300 and the introducing unit 500 may be connected to the optical system chamber 100.

The gas to be introduced is not limited to Ar, but may be any other gas such as Xe, as long as it is made into plasma by VUV or EUV. Also, the gas to be made into plasma by using a remote plasma generator is not limited to Ar. Other gas such as Xe may be used as long as it can be made into plasma by using a remote plasma generator.

The embodiments of the present disclosure are explained above. However, the present disclosure includes appropriate modifications that do not spoil the object and the advantages of the present disclosure. Further, the present disclosure is not limited by the embodiments explained above.

The first to fourth embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. An optical apparatus comprising:
a light source configured to generate light including EUV light;
a chamber in which a target object to be irradiated with the light is disposed;
an optical element provided in the chamber in order to guide the light;
an introducing unit configured to introduce argon into the chamber;
a power supply configured to apply a negative voltage to the optical element in the chamber;
an ammeter configured to measure an ion current flowing to the optical element; and
a control unit configured to control an introduction amount of the argon according to a measurement result of the ammeter.

2. The optical apparatus according to claim 1, wherein
the argon introduced into the chamber contains an argon gas,
the introducing unit includes an introducing pipe connected to the chamber,
the control unit controls a flow rate of the argon gas supplied into the chamber via the introducing pipe, and
the EUV light guided in the chamber converts the argon gas into argon plasma.

3. The optical apparatus according to claim 1, wherein
the introducing unit includes:
a remote plasma generation apparatus configured to generate argon plasma;
an introducing pipe provided between the remote plasma generation apparatus and the chamber; and
a variable conductance valve provided in the introducing pipe, and
the control unit controls conductance of the variable conductance valve to thereby control a flow rate of the argon plasma supplied into the chamber via the introducing pipe.

4. The optical apparatus according to claim 3, wherein a cooling mechanism that cools the introducing pipe is provided.

5. The optical apparatus according to claim 1, wherein the target object is an EUV mask including a pellicle.

6. The optical apparatus according to claim 1, wherein
the argon introduced into the chamber contains an argon gas,
the light source further generates the light including VUV light,
an oblique incidence mirror that reflects the VUV light is provided in the chamber,
the VUV light reflected by the oblique incidence mirror is made incident on the optical element, and
the VUV light guided into the chamber converts the argon gas into argon plasma.

7. A method of preventing contamination of an optical apparatus including:
a light source configured to generate light including EUV light;
a chamber in which a target object to be irradiated with the light is disposed; and
an optical element provided in the chamber in order to guide the light,
the method comprising:
a step of introducing argon into the chamber;
a step of applying a negative voltage to the optical element in the chamber;
a step of measuring an ion current flowing to the optical element; and
a step of controlling an introduction amount of the argon according to a measurement result of the ion current.

8. The method of preventing contamination of the optical apparatus according to claim 7, wherein
an introducing pipe is connected to the chamber,
in the step of introducing argon into the chamber,
the argon introduced into the chamber contains an argon gas,
in the step of controlling an introduction amount of the argon according to a measurement result of the ion current,
a flow rate of the argon gas supplied into the chamber via the introducing pipe is controlled according to the measurement result, and
the EUV light guided into the chamber converts the argon gas into argon plasma.

9. The method of preventing contamination of the optical apparatus according to claim 7, wherein
the optical apparatus includes:
a remote plasma generation apparatus configured to generate argon plasma;
an introducing pipe provided between the remote plasma generation apparatus and the chamber; and
a variable conductance valve provided in the introducing pipe,
in the step of introducing argon into the chamber,
the argon introduced into the chamber contains the argon plasma, and
in the step of controlling an introduction amount of the argon according to a measurement result of the ion current,
conductance of the variable conductance valve is controlled according to the measurement result to control a flow rate of the argon plasma supplied into the chamber via the introducing pipe.

10. The method of preventing contamination of the optical apparatus according to claim 9, wherein a cooling mechanism that cools the introducing pipe is provided.

11. The method of preventing contamination of the optical apparatus according to claim 7, wherein the target object is an EUV mask including a pellicle.

12. The method of preventing contamination of the optical apparatus according to claim 7, wherein
the light source further generates the light including VUV light,
an introducing pipe is connected to the chamber,
an oblique incidence mirror that reflects the VUV light is provided in the chamber,
the VUV light reflected by the oblique incidence mirror is made incident on the optical element,
in the step of introducing argon into the chamber,
the argon introduced into the chamber contains an argon gas,
in the step of controlling an introduction amount of the argon according to a measurement result of the ion current,
a flow rate of the argon gas supplied into the chamber via the introducing pipe is controlled according to the measurement result, and the VUV light guided into the chamber converts the argon gas into argon plasma.
